(19) United States
(12) Patent Application Publication
(10) Pub. No.: US 2004/0184272 A1
(43) Pub. Date: Sep. 23, 2004

(54) Substrate for light-emitting diode (LED) mounting including heat dissipation structures, and lighting assembly including same

(76) Inventors: Steven A. Wright, La Jolla, CA (US); Patrick Mullins, San Diego, CA (US)

Correspondence Address: LAW OFFICES OF ERIC KARICH, 2807 ST. MARK DR., MANSFIELD, TX, 76063, US

(21) Appl. No.: 10/805,920

(22) Filed: Mar. 22, 2004

Related U.S. Application Data
(60) Provisional application No. 60/456,111, filed on Mar. 20, 2003.

(51) Int. Cl. H01L 23/36; F21V 29/00

(52) U.S. Cl. 362/373; 362/249; 362/800; 257/706

(57) ABSTRACT

A disclosed substrate includes an electrically insulating circuit board, a pair of electrical lead pads adapted for mounting a light-emitting diode (LED) on a first surface, and a heat dissipating structure on the first surface. The heat dissipating structure includes an LED thermal pad adapted to abut the LED when mounted on the electrical lead pads, and a heat dissipation region extending from, and thermally coupled to, the LED thermal pad. The substrate also includes a thermally conductive plating on a second surface of the substrate opposite the heat dissipation region. A described lighting assembly includes the substrate, multiple LEDs connected to the electrical lead pads of the substrate, and multiple traces of the substrate connect the LEDs in a series circuit electrically isolated from the heat dissipating structures.

### CROSS-REFERENCE TO RELATED APPLICATIONS

The applications for a utility patent claims the benefit of U.S. Provisional Application No. 60/456,111, filed Mar. 20, 2003. The previous application is hereby incorporated by reference in its entirety.

### STATEMENT REGARDING FEDERALLY SPONSORED RESEARCH

Not Applicable

### BACKGROUND OF THE INVENTION

1. Field of the Invention

This invention relates generally to circuit boards for lighting assemblies, and more particularly to circuit boards with improved heat dissipation qualities, the circuit boards being particularly suitable for use with lighting assemblies that include high concentrations of light-emitting diodes (LEDs).

2. Description of Related Art

Due the their many advantages over incandescent lamps, light-emitting diodes (LEDs) are replacing incandescent lamps in many applications. For example, LEDs are in general more efficient, last longer, and are more durable than incandescent lamps. LEDs are typically at least 4 times more efficient at generating light than incandescent lamps. Unlike incandescent lamps, LEDs are extremely shock resistant. While an incandescent light bulb may produce light for 1,000 operating hours, many LEDs can provide 100,000 hours of continuous use.

In order to form light sources that can produce light with intensities greater than is possible with a single LED, multiple LEDs are often arranged to form two-dimensional arrays (i.e., LED arrays) wherein several LEDs produce light at the same time. Light-emitting diodes of LED arrays are often mounted on printed circuit boards (PCBs). A typical PCB includes multiple electrically conductive regions (i.e., pads) formed on a substantially planar surface of an insulating material (e.g., a fiberglass-epoxy composite material). The pads are provided for making electrical connections to leads of electrical components (e.g., resistors, capacitors, integrated circuits, etc.), and are typically arranged according to component lead layouts. Electrically conductive traces or tracks interconnect the pads to form one or more electrical circuits.

In general, the lifetime of an LED is inversely proportional to the operating temperature of the LED. For example, it has been reported that while the lifetime of an LED may approach 100,000 hours when operated at room temperature (25 degrees Celsius), operation of the LED at temperatures of about 90 degrees Celsius may reduce the LED lifetime to less than 7,000 hours. A problem arises in LED arrays in that it is often difficult to remove heat energy dissipated by the LEDs during operation, especially when the LED arrays densely packed into a small area that is sealed to prevent intrusion by water, small particles, etc. The problem can be exacerbated if the LEDs are positioned in sunlight such that solar heating occurs.

There are several references that teach printed circuit boards that provide improved heat dissipation. Hochstein, U.S. Pat. No. 6,045,240, for example, uses heat conducting pads on a circuitboard as both conductors and heat dissipation tools. Each of the pads extends through the circuit board via plated through-holes (or vias) for dissipating heat to a heat dissipation surface on the rear of the circuitboard.

While this is similar to the present invention, the Hockstein substrate takes a different approach to electrically isolating the heat dissipation surface from the LEDs mounted on the circuitboard. The Hochstein approach requires that the rear heat dissipation surface be electronically isolated from the circuitboard with an adhesive (58) and a non-conductive spacer (56), as best shown in FIG. 4. Not only do these layers add to the expense of the substrate, they can also lead to failure of the substrate if the layers are scratched during production. Furthermore, the positive and negative leads provide only a small surface area which is not able to dissipate heat effectively through the electrically insulating material to the heat sink.

It is an important improvement of the present invention that the heat dissipation surface is in direct contact with the circuitboard, and does not require an insulating material in between.

Another approach is taken in the next group of patents, Hochstein U.S Pat. No. 6,428,189 B1, Hochstein, U.S. Pat. No. 6,517,218 B2, Hochstein, Canada 2 342 140, and Dry, U.S. Pat. No. 6,573,536. In this approach, a base of each of the LEDs is in direct contact with a heat dissipating layer on the back of the circuit board through an aperture through the circuit board. The LEDs themselves are each mounted over and partially through one of the apertures so that they are in contact with the heat dissipating layer on the back surface of the circuit board, either directly or through a thermally coupling agent or layer.

Durocher et al., U.S. Pat. No. 6,614,103, teaches a flexible circuit module that has at least one rigid carrier, at least one solid state device mounted over a first side of the at least one rigid carrier, a flexible base supporting a second side of the at least one rigid carrier, a conductive interconnect pattern on the flexible base, and a plurality of feed through electrodes extending from the first side to the second side of the at least one rigid carrier and electrically connecting the conductive interconnect pattern with the at least one of a plurality of the solid state devices. The solid state devices may be LED chips to form an LED array module.

Ceramic and aluminum circuit boards are described in many of the prior art references. Biebl et al., U.S. Pat. No. 6,375,340 B1, describes a optoelectronic component group. The component group has at least two LEDs which are mounted on a support. The support is composed of a material having a thermal conductivity of better than 1.5 W/K.times.m, for example ceramic or composite material.

Chen et al., U.S. Pat. No. 6,392,888 B 1, describes a heat dissipation assembly, comprising of a printed circuit board (PCB), a chip and a heat sink. The PCB comprises a grounding circuit and four through apertures in the grounding circuit. The chip is mounted on the PCB, and is surrounded by the through apertures. The heat sink has four metal columns depending from a bottom surface of a base thereof, the columns corresponding to the four through apertures. A method of assembling the heat dissipation assembly includes the steps of: mounting a chip on a PCB; inserting metal columns of a heat sink into corresponding through apertures of the PCB; and welding the metal columns in the through apertures so that the heat sink is in intimate thermal contact with an upper surface of the chip.

Lin, U.S. Pat. No. 6,590,773 B1, describes a heat dissipation device which is mounted to a light emitting diode device for removing heat from the light emitting diode. This includes a substrate having a top side on which a light-emitting unit is formed and an opposite bottom side from which terminals extend. The heat dissipation device includes a plate made of heat conductive material and forming a receptacle for receiving and at least partially enclosing and physically engaging the substrate of the light emitting diode device for enhancing heat removal from the light emitting diode device.

Known LED heat dissipation structures are complex and costly to fabricate, and are not as effective in heat dissipation. It would be beneficial to have an LED heat dissipating structure that is relatively simple structure and efficiently dissipates heat generated by LEDs during operation such that the operating temperatures of the LEDs are reduced and the lifetimes of the LEDs are increased.

### SUMMARY OF THE INVENTION

A disclosed substrate is adapted for mounting a high density of light-emitting diodes (LEDs) and effectively dissipating heat from the LEDs to maximize the efficiency and life expectancy of the LEDs. The substrate includes a circuit board having opposed first and second surfaces, and constructed of an electrically insulating material. The substrate also includes a pair of electrical lead pads adapted for mounting the LED on the first surface, and a heat dissipating structure disposed on the first surface. The heat dissipating structure includes an LED thermal pad adapted to abut the LED when the LED is mounted on the pair of electrical lead pads, and a heat dissipation region extending from, and thermally coupled to, the LED thermal pad. The substrate also includes a thermally conductive plating on the second surface opposite the heat dissipation region.

A described lighting assembly includes a substrate having multiple pairs of electrical lead pads, each adapted for mounting an LED on a first surface, and multiple heat dissipating structures disposed on the first surface. The lighting assembly also includes multiple LEDs, each connected to one of the pairs of electrical lead pads. The substrate further includes multiple electrically conductive traces disposed between the pairs of electrical lead pads such that the LEDs are electrically connected in series via a circuit electrically isolated from the heat dissipating structures.

Other features and advantages of the present invention will become apparent from the following more detailed description, taken in conjunction with the accompanying drawings, which illustrate, by way of example, the principles of the invention.

### BRIEF DESCRIPTION OF THE DRAWING

The accompanying drawings illustrate the present invention. In such drawings:

FIG. 1 is a top plan view of one embodiment of a lighting assembly including multiple structures for mounting light-emitting diodes (LEDs) formed on a printed circuit board (PCB), wherein the lighting assembly includes a printed circuit board having heat dissipation regions on one side thermally coupled to a thermally conductive layer on an opposite side via spokes formed in the heat dissipation regions;

FIG. 2 is a sectional view thereof taken along line 2-2 in FIG. 1;

FIG. 3 is a sectional view thereof taken along line 3-3 in FIG. 1; and

FIG. 4 is an alternative embodiment of the lighting assembly shown in FIG. 3.

### DETAILED DESCRIPTION OF THE INVENTION

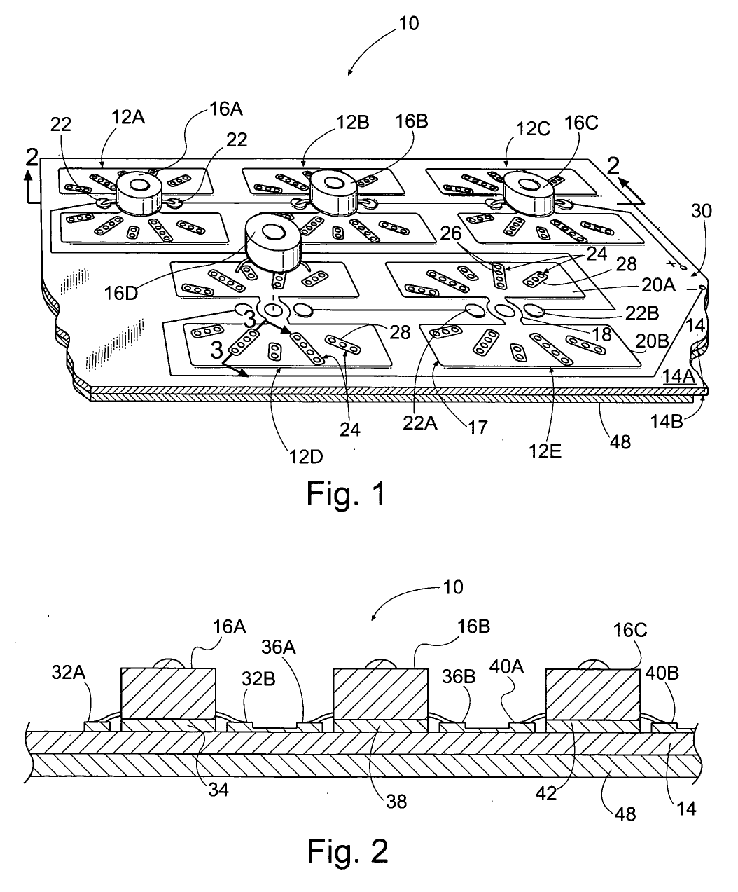

FIG. 1 is a top plan view of one embodiment of a lighting assembly 10 including 5 structures 12A-12E for mounting a plurality of light-emitting diodes (LEDs) formed on a printed circuit board (PCB) 14. Three LEDs 16A-16C are shown mounted to structures 12A-12C, respectively, and a fourth LED 16D is shown above the structure 12D. The 5 structures 12A-12E are referred to collectively as the structures 12.

In the embodiment of FIG. 1, the PCB 14 includes an electrically insulating base material (e.g., a fiberglass-epoxy composite base material) having two opposed sides, first and second surfaces 14A and 14B. In general, an electrically and thermally conductive layer (e.g., a metal layer such as a copper layer) exists on each of the two opposed sides of the base material. The structures 12, described below, are formed from the copper layer formed on the first surface 14A. A thermally conductive plating 48 is formed from the copper layer formed on the second surface 14.

The structures 12 include features formed in the electrically conductive layer on one of the two opposed sides of the base material. In general, the features may be formed via an additive process or a subtractive process. In a typical subtractive process the electrically conductive layer is initially continuous, and portions of the electrically conductive layer are removed (i.e., the electrically conductive layer is patterned) to form the features.

In the embodiment of FIG. 1, the structure 12E, typical of each of the structures 12, includes a heat dissipating structure 17 and a pair of electrical lead pads 22A and 22B positioned adjacent to the heat dissipating structure 17. The heat dissipating structure 17 may include a centrally located LED thermal pad 18 and a pair of heat dissipation regions 20A and 20B extending from an upper side and a lower side, respectively, of the LED thermal pad 18. The pair of electrical lead pads 22A and 22B are positioned on a left side and a right side, respectively, of the LED thermal pad 18. The LED thermal pad 18 is adapted to contact an underside surface of an LED when the LED is mounted on the pair of electrical lead pads 22A and 22B.

While the preferred embodiment illustrates a structure 12 that includes a pair of electrical lead pads 22A and 22B that are separate from and electrically isolated from the thermal pad 18, it should be noted that this is not necessarily required. For example, the thermal pad 18 could also form one of the lead pads 22A or 22B, or the two could be electrically connected in another manner. Such an embodiment should be considered expressly within the scope of the claimed invention. In such an alternative embodiment, it is preferred that the cathode lead pad should be electrically and thermally joined with the thermal pad 18 and the pair of heat dissipation regions 20A and 20B, to better dissipate the heat generated at the cathode of the LED.

In a preferred embodiment, the electrically conductive layers of the PCB 14 are layers of a metal such as copper. As a result, the LED thermal pad 18, the heat dissipation regions 20A and 20B, and the electrical lead pads 22A and 22B are all made of the metal, and the heat dissipation regions 20A and 20B extending from the LED thermal pad 18 are thermally coupled to LED thermal pad 18.

As the structure 12E is typical of each of the structures 12, each of the structures 12 has a pair of heat dissipation regions 20A and 20B extending from an LED thermal pad 18. The LED thermal pad 18 and the heat dissipation regions 20A and 20B are thermally coupled to the electrically conductive layer on the opposite side of the PCB 14 via the base material of the PCB 14. In one embodiment, the heat dissipation regions 20A and 20B together have a surface area (in contact with the base material of the PCB 14) that is at least twice the surface area of the LED thermal pad 18, and most preferably more than four times the surface area. Due to the relatively large areas of the heat dissipation regions 20A and 20B, the thermal resistance of the thermal path between the LED thermal pad 18 and the thermally conductive plating 48 on the second surface 14B of the PCB 14 is advantageously reduced. The thermally conductive plating 48 is disposed directly on the second surface 14B of the PCB 14, and is not separated with an electrically insulating material as is done in the prior art.

In the embodiment of FIG. 1, multiple optional plated through holes (i.e., vias) 26 are used to further reduce the thermal resistance of the thermal path between the LED thermal pad 18 and the electrically conductive layer on the opposite side of the PCB 14. In one embodiment, the through holes 26 are arranged in spokes 24 that extend across different portions of the heat dissipation region 20A. The spokes 24 are preferably oriented along lines extending radially outward from a center of the thermal pad 18. Multiple plated through holes 26 connect each of the portions of the heat dissipation region 20A in which the spokes 24 exist to the thermally conductive plating 48.

The spokes 24 are electrically isolated from a remainder of the heat dissipation region 20A by electrically isolating regions 28, such as narrow gaps or a spacer made of a non-electrically-conductive material. This electrical isolation is necessary in embodiments where a voltage level impressed on the portions of the electrically conductive layer forming the LED thermal layer 18 and the heat dissipation regions 20A and 20B (e.g., via an LED mounted to the corresponding structure 12) differs from a voltage level impressed on the electrically conductive layer on the opposite sides of the PCB 14. It is noted that this electrical isolation may not be required in other embodiments.

As the structure 12E is typical of each of the structures 12, each of the structures 12 has a pair of heat dissipation regions 20 extending from an LED thermal pad 18. Each of the heat dissipation regions 20 has five spokes 24 in portions of the heat dissipation regions 20 electrically isolated from, but thermally coupled to, remainders of the heat dissipation regions 20. Multiple plated through holes (i.e., vias) 26 connect each of the portions of the heat dissipation regions 20 to the electrically conductive layer on the opposite side of the PCB 14.

In one embodiment, the electrically conductive layers of the PCB 14 are layers of a metal such as copper, and the plated through holes (i.e., vias) 26 are formed from a metal such as copper. Narrow gaps 28 in the portions of the metal layer forming the heat dissipation regions 20 separate the portions of the heat dissipation regions 20 in which the spokes 24 exist from the remainders of the heat dissipation regions 20. The narrow gaps 28 electrically isolate the portions of the heat dissipation regions 20 in which the spokes 24 exist from the remainders of the heat dissipation regions 20. The portions of the heat dissipation regions 20 in which the spokes 24 exist are thermally coupled to the remainders of the heat dissipation regions 20 via the underlying base material of the PCB 14.

In addition, the narrow gaps 28 may be filled with an electrically insulating material that is also non-electrically-conductive. In this situation, the portions of the heat dissipation regions 20 in which the spokes 24 exist are more effectively thermally coupled to the remainders of the heat dissipation regions 20 via the material filling the narrow gaps 28.

The metal plated through holes 26 thermally couple the portions of the heat dissipation regions 20 in which the spokes 24 exist to the electrically conductive layer on the opposite side of the PCB 14. As a result, the thermal resistance of the thermal path between the LED thermal pad 18 and the thermally conductive plating 48 is advantageously reduced.

As the structure 12E is typical of each of the structures 12, each of the structures 12 has a pair of electrical lead pads 22. In the embodiment of FIG. 1, the electrical lead pads 22 of the structures 12 are connected in series between a pair of electrical connectors 24 by traces or tracks also formed in the electrically conductive layer. As a result, the LEDs 16A-16C, the LED 16D when mounted to the electrical lead pads 22 of the structure 12D, and another LED mounted to the electrical lead pads 22A and 22B of the structure 12E, produce light simultaneously when electrical power is applied to the electrical connectors 24.

FIG. 2 is a cross-sectional view of a portion of the lighting assembly 10 of FIG. 1 as indicated in FIG. 1. As shown in FIG. 2, the pair of electrical lead pads 22 of the structure 12A (FIG. 1) are labeled 32A and 32B, and the LED thermal pad 18 (shown as part of structure 12E, but not visible as part of structure 12A) of the structure 12A (FIG. 1) is labeled 34. The pair of electrical lead pads 22 of the structure 12B (FIG. 1) are labeled 36A and 36B, and the LED thermal pad 18 of the structure 12B (FIG. 1) is labeled 38. The pair of electrical lead pads 22 of the structure 12C (FIG. 1) are labeled 40A and 40B, and LED thermal pad 18 of the structure 12C (FIG. 1) is labeled 42.

In FIG. 2, the leads of the surface mount LED 16A are connected to the pads 32A and 32B, and an underside surface of the LED 16A contacts an upper surface of the LED thermal pad 34. The axial gull wing leads of the surface mount LED 16B are connected to the pads 36A and 36B, and an underside surface of the LED 16B contacts an upper surface of the LED thermal pad 38. Similarly, the axial gull wing leads of the surface mount LED 16C are connected to the pads 40A and 40B, and an underside surface of the LED 16C contacts an upper surface of the LED thermal pad 42.

FIG. 2 also shows the electrically insulating base material 14 of the PCB 14, the electrically conductive layer 40 in which the electrical lead pads 32A, 32B, 36A, 36B, 40A, and 40B and the LED thermal pads 34, 38, and 42 exist, and the thermally conductive plating 48 on the opposite side of the base material 14.

Portions of the heat energy dissipated by the LEDs 16A-16C during operation are transferred to the LED thermal pads 34, 38, and 42, respectively, via conduction. This heat energy is in turn conducted along the above described thermals path from the LED thermal pads 34, 38, and 42 to the thermally conductive plating 48 on the opposite side of the PCB 14. As a result of the conduction of heat away from the LEDs 16A-16C during operation, the operating temperatures of the LEDs 16A-16C are reduced, and the lifetimes of the LEDs 16A-16C are expectedly increased.

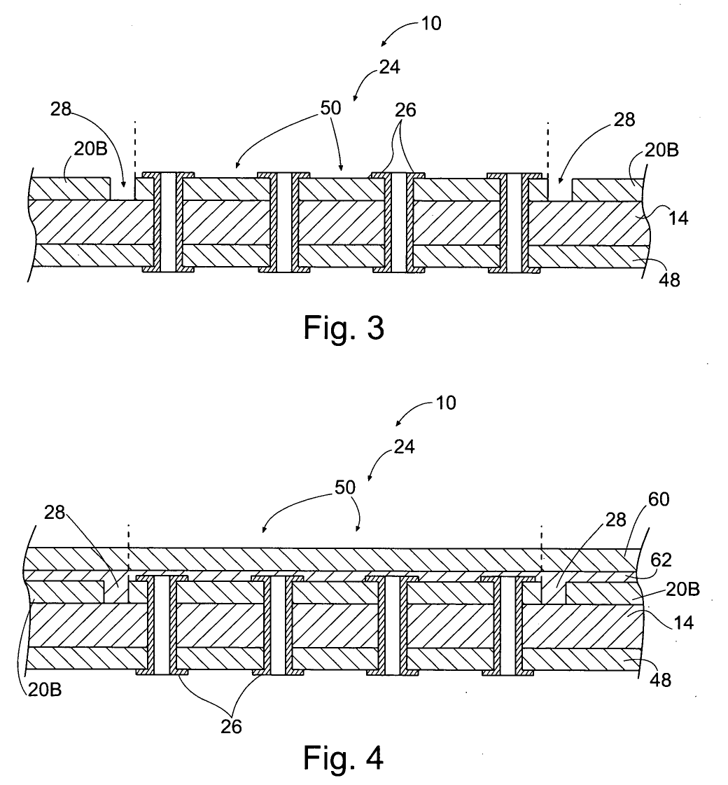

FIG. 3 is a cross-sectional view of one of the spokes 24 of the lighting assembly 10 of FIG. 1 as indicated in FIG. 1. As indicated in FIG. 3, the multiple plated through holes 26 connect a portion 50 of a heat dissipation region 20B of FIG. 1 to the thermally conductive plating 48 on the opposite side of the PCB 14. As described above, the narrow gaps 28 separate the portion 50 from a remainder of the heat dissipation region 20B, electrically isolating the portion 50 from the remainder of the heat dissipation region 20B. The portion 50 is thermally coupled to the remainder of the heat dissipation region 20B via the underlying base material 14 of the PCB 14.

As described above, the narrow gaps 28 may be filled with an electrically insulating material that is also thermally conductive. In this situation, the portion 50 of the heat dissipation region 20B is also thermally coupled to the remainder of the heat dissipation region 20B via the material filling the narrow gaps 28.

FIG. 4 is another embodiment of the spokes 24 shown in FIG. 3. In this embodiment, a thermally conductive layer 60, electrically insulated from the heat dissipating structure 17 by a dielectric layer 62, is used to reduce the thermal resistance of the thermal path between the spoke 24 and the surrounding remainder of the heat dissipation region 20B. As in FIG. 3, the multiple plated through holes (i.e., vias) 26 connect the portion 50 of the heat dissipation region 20B of FIG. 1 to the thermally conductive plating 48 on the opposite side of the PCB 14. As described above, the narrow gaps 28 separate the portion 50 from the remainder of the heat dissipation region 20B, electrically isolating the portion 50 from the remainder of the heat dissipation region 20B.

In the embodiment of FIG. 4, the through holes 26 and the portion 50 are thermally coupled to the remainder of the heat dissipation region 20B via the thermally conductive layer 60 and the dielectric layer 62, in addition to the PCB 14. As a result of the increased conduction of heat away from the LEDs 16A-16C during operation, the operating temperatures of the LEDs 16A-16C are further reduced, and the lifetimes of the LEDs 16A-16C are expectedly further increased.

The thermally conductive layer 60 may be, for example, a thin sheet of a metal such as copper (e.g., a piece of copper foil), and the dielectric layer 62 may be a sheet of a polyimide material such as Kapton® (E.I. duPont de Nemours & Co., Wilmington, Del.). In one exemplary embodiment, the dielectric layer 62 is a 0.004 inch (4 mil) thick sheet of Kapton® polyimide material. A thin layer of an adhesive material may be used to attach an underside surface of the dielectric layer 62 to upper surfaces of the features in the electrically conductive layer 46, and another thin layer of the adhesive material may be used to bond an upper surface of the dielectric layer 62 to an underside surface of the thermally conductive layer 60. In this embodiment, the narrow gaps 28 may be filled with the electrically insulating material of the dielectric layer 62.

While the invention has been described with reference to at least one preferred embodiment, it is to be clearly understood by those skilled in the art that the invention is not limited thereto. Rather, the scope of the invention is to be interpreted only in conjunction with the appended claims.

What is claimed is:

1. A substrate adapted for mounting a light-emitting diode (LED), the substrate comprising;
a circuit board having opposed first and second surfaces, the circuit board being constructed of an electrically insulating material;
a pair of electrical lead pads adapted for mounting the LED on the first surface of the circuit board;
a heat dissipating structure disposed on the first surface, having:
an LED thermal pad adapted to abut the LED when the LED is mounted on the pair of electrical lead pads, and
a heat dissipation region extending from and thermally coupled to the LED thermal pad; and
a thermally conductive plating disposed directly on the second surface of the circuitboard opposite the heat dissipation region.

2. The substrate as recited in claim 1, wherein the heat dissipation region has at least twice the area of the LED thermal pad.

3. The substrate as recited in claim 1, wherein the heat dissipation region includes first and second regions extending from opposite sides of the LED thermal pad.

4. The substrate as recited in claim 1, wherein the heat dissipating structure includes an isolated region that is electrically isolated from the heat dissipation region, the isolated region having a plurality of heat conducting vias that extend through the circuit board and are thermally coupled with the thermally conductive region.

5. The substrate as recited in claim 4, wherein the vias are arranged in spokes that extend outwardly from the LED thermal pad.

6. The substrate as recited in claim 4, wherein the vias are within the heat dissipating structure, but electrically isolated from the heat dissipating structure by a non-electrically-conductive region.

7. The substrate as recited in claim 4, wherein the vias and the heat dissipation region are thermally connected with a conductive bridge layer opposite the circuit board, the conductive bridge layer being electrically isolated from the vias and/or the heat dissipation region by a dielectric layer.

8. The substrate as recited in claim 4, wherein the vias are copper plated through-holes.

9. A lighting assembly comprising;
a substrate, comprising:
a circuit board having opposed first and second surfaces, the circuit board being constructed of an electrically insulating material;
a plurality of pairs of electrical lead pads each adapted for mounting a light-emitting diode (LED) on the first surface of the circuit board;
a plurality of heat dissipating structures disposed on the first surface, each having:
an LED thermal pad adapted to abut the LED when the LED is mounted on the pair of electrical lead pads, and
a heat dissipation region extending from and thermally coupled to the LED thermal pad;
a thermally conductive plating on the second surface opposite the heat dissipation region;
a plurality of LEDs each connected to one of the pair of electrical lead pads of the substrate; and
wherein the substrate further comprises a plurality of electrically conductive traces disposed between the pairs of electrical lead pads such that the LEDs are electrically connected in series via a circuit electrically isolated from the heat dissipating structures.

10. The lighting assembly as recited in claim 9, wherein the heat dissipation region has at least twice the area of the LED thermal pad.

11. The lighting assembly as recited in claim 9, wherein the heat dissipation region includes first and second regions extending from opposite sides of the LED thermal pad.

12. The lighting assembly as recited in claim 9, wherein the heat dissipating structure includes an isolated region that is electrically isolated from the heat dissipation region, the isolated region having a plurality of heat conducting vias that extend through the circuit board and are thermally coupled with the thermally conductive region.

13. The lighting assembly as recited in claim 12, wherein the vias are arranged in spokes that extend outwardly from the LED thermal pad.

14. The lighting assembly as recited in claim 12, wherein the vias are within the heat dissipating structure, but electrically isolated from the heat dissipating structure by a non-electrically-conductive region.

15. The lighting assembly as recited in claim 12, wherein the vias and the heat dissipation region are thermally connected with a conductive bridge layer opposite the circuit board, the conductive bridge layer being electrically isolated from the vias and/or the heat dissipation region by a dielectric layer.
